(19) United States
(12) Patent Application Publication
(10) Pub. No.: US 2025/0253187 A1
(43) Pub. Date: Aug. 7, 2025

(54) FLOWABLE CHEMICAL VAPOR DEPOSITION (FCVD) AND SACRIFICIAL ETCH PROTECTION PROCESSES

(71) Applicant: Applied Materials, Inc., Santa Clara, CA (US)

(72) Inventors: KEITH WONG, North Bend, WA (US); MICHAEL BREEDEN, Santa Clara, CA (US); SRINIVAS D. NEMANI, Saratoga, CA (US)

(21) Appl. No.: 18/433,246

(22) Filed: Feb. 5, 2024

(51) Int. Cl. H01L 21/762; C23C 16/04; C23C 16/26; C23C 16/455; C23C 16/505; C23C 16/56; H01L 21/02

(52) U.S. Cl. CPC H01L 21/76224; C23C 16/045; C23C 16/26; C23C 16/45536; C23C 16/505; C23C 16/56; H01L 21/02205; H01L 21/02274; H01L 21/0228

(57) ABSTRACT

Embodiments disclosed herein include a method of depositing a carbon layer on a substrate. In an embodiment, the method comprises flowing a first precursor comprising carbon into a chamber. In an embodiment, the method continues with flowing a second precursor comprising nitrogen into the chamber. In an embodiment, a pulsed RF plasma source is applied to the first precursor and the second precursor. In an embodiment, the first precursor and the second precursor react in response to the pulsed RF plasma source to form a flowable polymerized layer that is deposited on the substrate.

### BACKGROUND

### 1) Field

Embodiments relate to the field of semiconductor manufacturing and, in particular, apparatuses and methods for depositing flowable carbon layers with flowable chemical vapor deposition (FCVD) processes.

### 2) Description of Related Art

Semiconductor device architectures are increasingly moving towards the use of three-dimensional (3D) structures. Fin-based devices may include a plurality of fins that are laterally adjacent to each and spaced apart by a trench. Due to the high aspect ratio of such trenches, filling the trenches is difficult. Further, advances beyond fin-based transistors continue. Architectures such as gate-all-around (GAA) transistors have been proposed. In GAA architectures, semiconductor sheets or semiconductor wires (e.g., nano-sheets or nano-wires) are provided in a stack within a fin. In such transistor devices, even greater control of the layer deposition in the trenches between fins is desired.

Existing layer deposition processes do not currently allow for high aspect ratio trench filling (i.e., between adjacent fins). Conformal deposition processes (e.g., atomic layer deposition (ALD)) have been proposed. However, the conformal process may result in pinching between the fins. That is, the upper portion of the fin may exhibit faster layer growth. When the layer growth from neighboring fins converge, void formation can be a problem within the device.

### SUMMARY

Embodiments disclosed herein include a method of depositing a carbon layer on a substrate. In an embodiment, the method comprises flowing a first precursor comprising carbon into a chamber. In an embodiment, the method continues with flowing a second precursor comprising nitrogen into the chamber. In an embodiment, a pulsed RF plasma source is applied to the first precursor and the second precursor. In an embodiment, the first precursor and the second precursor react in response to the pulsed RF plasma source to form a flowable polymerized layer that is deposited on the substrate.

Embodiments may further comprise a method for filling a trench on a substrate. In an embodiment, the method comprises depositing a first layer over the substrate that comprises a first fin and a second fin, where the trench is between the first fin and the second fin. In an embodiment, the method further comprises depositing a second layer over the first layer with a flowable deposition process, where a top surface of the second layer is above a top surface of the first layer. In an embodiment, the method further comprises recessing the second layer so that the top surface of the second layer is below a top surface of the first layer, and removing a top portion of the first layer. In an embodiment, the second layer is then removed.

Embodiments may also include a method for forming an isolation layer at a bottom of a trench on a substrate. In an embodiment, the method comprises depositing a first layer over the substrate with a first fin and a second fin, where the trench is between the first fin and the second fin, and depositing a second layer over the first layer with a flowable deposition process, where a top surface of the second layer is below at least a portion of the first layer. In an embodiment, the method may further comprise removing the portion of the first layer, and removing the second layer.

### BRIEF DESCRIPTION OF THE DRAWINGS

FIG. 1 is a cross-sectional illustration of a semiconductor device that comprises a plurality of fins that are covered by a layer that pinches together at the top of the fins to generate voids in the trenches, in accordance with an embodiment.

FIG. 2 is a cross-sectional illustration of a processing tool that can be used in order to deposit flowable carbon layers with a flowable chemical vapor deposition (FCVD) process that allows for improved filling of high aspect ratio trenches, in accordance with an embodiment.

FIG. 3A is a process flow diagram of an FCVD process for depositing a flowable carbon layer, in accordance with an embodiment.

FIG. 3B is a cross-sectional illustration of a semiconductor device with fins that define trenches that are fully filled with a carbon layer that is void-free, in accordance with an embodiment.

FIGS. 4A-4F are cross-sectional illustrations depicting a process for forming a semiconductor device with fully filled trenches through the use of a sacrificial flowable carbon layer, in accordance with an embodiment.

FIG. 5 is a process flow diagram depicting a process for forming a semiconductor device with fully filled trenches through the use of a sacrificial flowable carbon layer, in accordance with an embodiment.

FIGS. 6A-6D are cross-sectional illustrations depicting a process for forming a semiconductor device with insulated layers at the bottom of trenches between fins that are formed with the use of a sacrificial flowable carbon layer, in accordance with an embodiment.

FIG. 7 is a process flow diagram depicting a process for forming a semiconductor device with insulated layers at the bottom of trenches between fins that are formed with the use of a sacrificial flowable carbon layer, in accordance with an embodiment.

FIG. 8 illustrates a block diagram of an exemplary computer system that may be used in conjunction with a processing tool, in accordance with an embodiment.

### DETAILED DESCRIPTION

Embodiments described herein include systems and methods for depositing flowable carbon layers with flowable chemical vapor deposition (FCVD) processes. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, semiconductor devices are trending towards the inclusion of three-dimensional (3D) architectures. For example, 3D architectures may include fin-based transistors, gate-all-around (GAA) transistors that are embedded within fins, 3D memory devices, and the like. While 3D solutions provide enhanced performance, density, and other benefits, 3D solutions suffer from increased manufacturing complexity. A particular 3D manufacturing issue is the inadequate filling of high aspect ratio trenches. For example, the trenches between fins may need to be filled with insulating material in order to electrically isolate neighboring fins from each other.

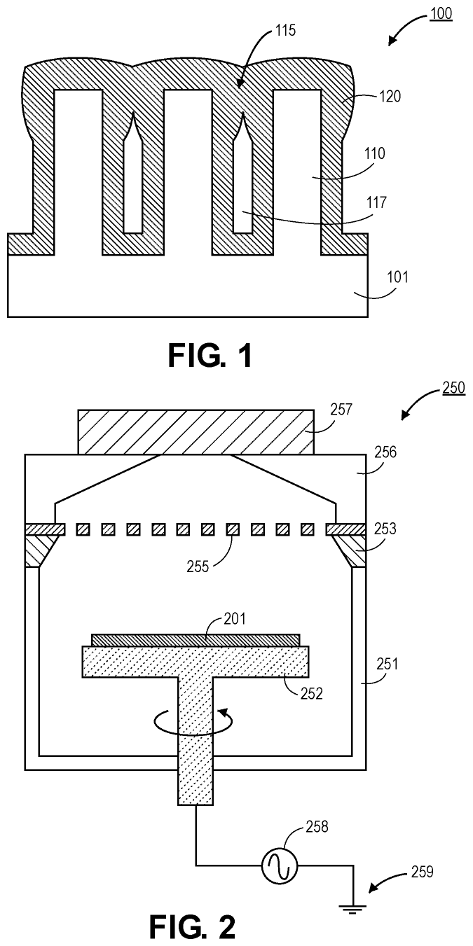

FIG. 1 is a cross-sectional illustration that depicts a common manufacturing defect in such a 3D semiconductor device 100. In an embodiment, the semiconductor device 100 comprises a substrate 101 with fins 110 that extend up from the substrate 101. In an embodiment, the substrate 101 may be a semiconductor material, such as silicon or the like. The fins 110 may also be a semiconductor material. The fins 110 may be the same material as the substrate 101, or the fins 110 may be a different material than the substrate 101. As will be described in greater detail below, the fins 110 may also comprise nano-sheets or nano-wires to enable GAA functionality.

In an embodiment, the fins 110 are high aspect ratio features. For example, a height:width aspect ratio of the fins 110 may be approximately 5:1 or greater, approximately 10:1 or greater, or approximately 20:1 or greater. Though, smaller aspect ratio fins 110 may also benefit from embodiments disclosed herein. As used herein, “approximately” may refer to a range of values within ten percent of the stated value. For example, approximately 10:1 may refer to a range of ratios between 9:1 and 11:1.

In an embodiment, the fins 110 may be spaced from each other in order to form trenches 115 between fins 110. The trenches 115 may also be high aspect ratio features. For example, the aspect ratio (depth:width) of the trenches 115 may be approximately 5:1 or greater, approximately 10:1 or greater, or approximately 20:1 or greater. Though, smaller aspect ratio trenches 115 may also benefit from embodiments disclosed herein.

The aspect ratio of the trenches 115 may result in inadequate filling with a layer 120. For example, the layer 120 may pinch together at a top of the trench 115. This pinching prevents further deposition of the layer 120 in the trench 115, and a void 117 is formed in the trench 115. Void 117 formation can lead to significant reliability issues for the semiconductor device 100, and should be avoided. In some instances, the layer 120 may suffer from void 117 formation even when highly conformal processes are used to deposit the layer 120. For example, atomic layer deposition (ALD), chemical vapor deposition (CVD), and/or the like have been shown to suffer from void 117 formation when dealing with high aspect ratio features.

Accordingly, embodiments disclosed herein may include the use of a layer that is deposited in a flowable state. Generally, the flowable layer is deposited as a polymeric material that has minimal cross-linking. This allows for free flow of oligomer chains in order to provide a liquid like behavior. When a flowable layer is deposited on the semiconductor device, the layer fills the trenches bottom up. That is, the flowable layer flows to the bottom of the trench instead of accumulating on the sidewalls of the fins. In this manner, there is no pinch-off at the top of the trench, and voids are avoided.

In a particular embodiment, the flowable state of the layer is generated through the use of a flowable chemical vapor deposition (FCVD) process. In an embodiment, the FCVD process includes the flow of two or more precursor gasses into a chamber. One of the precursor gasses may comprise nitrogen (e.g., ammonia) in order to initiate the polymerization of the layer.

In an embodiment, the FCVD process may also comprise a pulsed plasma deposition process. For example, a pulse frequency between 100 Hz and 100 kHz may be used in some embodiments. The pulsed plasma deposition may enable higher deposition rates. This allows for increased throughput and reduces costs. Additionally, the pulsed plasma deposition may allow reduced precursor consumption.

Referring now to FIG. 2, a cross-sectional illustration of a tool 250 is shown, in accordance with an embodiment. In an embodiment, the tool 250 may be a tool compatible with FCVD processes with pulsed plasma operations, such as those described in greater detail herein. For example, the tool 250 may comprise a chamber 251 capable of supporting a vacuum environment. A spacer 253 may support a showerhead 255, and an enclosure 256 or lid may cover the showerhead 255. A plasma source 257 may be coupled to the enclosure 256. The plasma source 257 may be a remote plasma source (RPS), an inductively coupled plasma (ICP) source, a capacitively coupled plasma (CCP) source, a microwave plasma source, or any other suitable plasma source. The plasma may operate at any suitable frequency. For example, plasma frequencies of approximately 2 MHz, approximately 13 MHz, approximately 27 MHz, approximately 40 MHz, or the like may be used. Power values between approximately 100 W and 1,000 W may also be used in some embodiments.

In an embodiment, the plasma may be used as part of the FCVD process in some embodiments. Precursor gasses may be fed into the chamber 251 for the FCVD process. Oligomers from the reaction may propagate to the substrate 201 for deposition of the flowable film. In an embodiment, the pedestal 252 may be rotatable, as indicated by the arrow.

In an embodiment, a bias 258 may be coupled between the pedestal 252 and a ground 259. The bias 258 may be a pulsed bias 258, such as an RF pulsed bias 258. For example, the RF pulsed bias 258 may include a pulse frequency between approximately 100 Hz and approximately 100 kHz. Though, any suitable frequency may be used in accordance with embodiments disclosed herein.

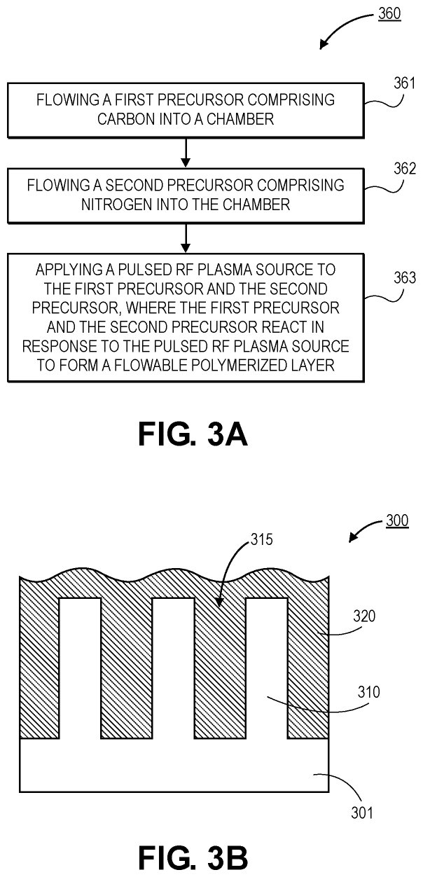

Referring now to FIG. 3A, a process flow diagram depicting a process 360 for depositing a flowable layer with a pulsed plasma FCVD process is shown, in accordance with an embodiment. In an embodiment, the process 360 may begin with operation 361, which comprises flowing a first precursor comprising carbon into a chamber. In an embodiment, the chamber may be similar to the chamber 251 of tool 250 described in greater detail herein. The first precursor may comprise an organic carbon molecule, such as a vinyl-containing organic molecule. For example, the first precursor may comprise 5-vinyl-2-norbornene, hexadiene, or the like. The first precursor may comprise acetylene in other embodiments.

In an embodiment, the process 360 may continue with operation 362, which comprises flowing a second precursor comprising nitrogen into the chamber. The nitrogen may include ammonia, or any other gaseous nitrogen containing molecule. More generally, the second precursor may comprise a radical initiator for polymerization to enable the generation of the flowable layer.

In an embodiment, the operations 361 and 362 may be implemented at the same time. That is, the first precursor and the second precursor may be flown into the chamber at the same time. Other embodiments include sequentially flowing the first precursor and the second precursor into the chamber with any number of cycles. The flow rates of the first precursor and the second precursor may be any suitable flow rates that enable generation of the flowable carbon layer. Embodiments may also include the flow of additional gasses to dilute one or both of the precursors, tune the uniformity of deposition, improve deposition rates, and/or induce etch-back during deposition to control film topography. For example, additional gasses may include one or more of argon, helium, nitrogen gas, or hydrogen.

In an embodiment, the process 360 may continue with operation 363, which comprises applying a pulsed RF plasma source to the first precursor and the second precursor. In an embodiment, the first precursor and the second precursor react in response to the pulsed RF plasma source to form a flowable polymerized layer. In an embodiment, the pulsed RF bias may include a pulse frequency between approximately 100 Hz and approximately 100 kHz. Though, any suitable frequency may be used in accordance with embodiments disclosed herein. The frequency of the plasma may be any suitable frequency, such as approximately 2 MHz, approximately 13 MHz, approximately 27 MHz, or approximately 40 MHz.

In an embodiment, the use of the first precursor and the second precursor in combination with a pulsed RF plasma source allows for lower temperature operating conditions. For example, substrate temperatures may be maintained below 100° C. In one embodiment, the substrate temperature may be maintained between approximately 0° C. and approximately 20° C. Pressure within the chamber may be maintained below approximately 50 torr. For example, pressures between approximately 1 torr and approximately 20 torr may be beneficial for some embodiments.

Referring now to FIG. 3B, a cross-sectional illustration of a semiconductor device 300 is shown, in accordance with an embodiment. In an embodiment, the semiconductor device 300 comprises a substrate 301 with fins 310 that extend up from the substrate 301. In an embodiment, the substrate 301 may be a semiconductor material, such as silicon or the like. The fins 310 may also be a semiconductor material. The fins 310 may be the same material as the substrate 301, or the fins 310 may be a different material than the substrate 301. As will be described in greater detail below, the fins 310 may also comprise nano-sheets or nano-wires to enable GAA functionality.

In an embodiment, the fins 310 are high aspect ratio features similar to the fins 110 described in greater detail above. The fins 310 may be spaced from each other in order to form trenches 315 between fins 310. The trenches 315 may also be high aspect ratio features, similar to trenches 115 described in greater detail above. The aspect ratio of the trenches 315 may result in 3D features that are difficult to fill.

However, when a pulsed plasma FCVD process is used to deposit the layer over the substrate 301, a bottom up filling process is provided. As such, the layer 320 flows to the bottom of the trenches 315 and fills up the trenches 315. That is, there is minimal (if any) sidewall deposition at the top of the fins 310. This prevents pinching off the trenches 315, and the trenches 315 can be filled in a substantially void-free manner. After the layer 320 extends above the top of the fins 310, the layer 320 may merge together and continue depositing in the vertical direction. The top surface of the layer 320 may have some undulation. Though, control of processing parameters (e.g., temperatures, pressures, precursor gas flow rates, buffer gas concentrations, plasma pulse frequency, etc.) may be used to minimize or eliminate surface undulation, if necessary.

In the embodiments described herein, the layer 320 is generally a carbon containing layer. The layer 320 may also comprise elements other than carbon, such as silicon, nitrogen, oxygen, hydrogen, and/or the like. The layer 320 may be retained in the final structure of the semiconductor device 300. In other embodiments, the layer 320 may be used as a sacrificial layer for other patterning purposes. In such an embodiment, the layer 320 may not be present in the final structure of the semiconductor device 300. Some examples of the use of a sacrificial carbon layer deposited with a pulsed plasma FCVD process are disclosed in greater detail herein.

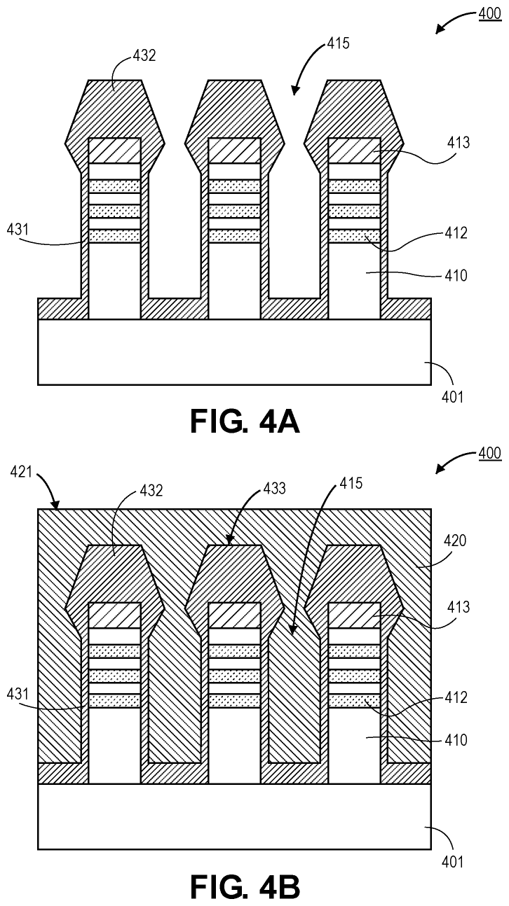

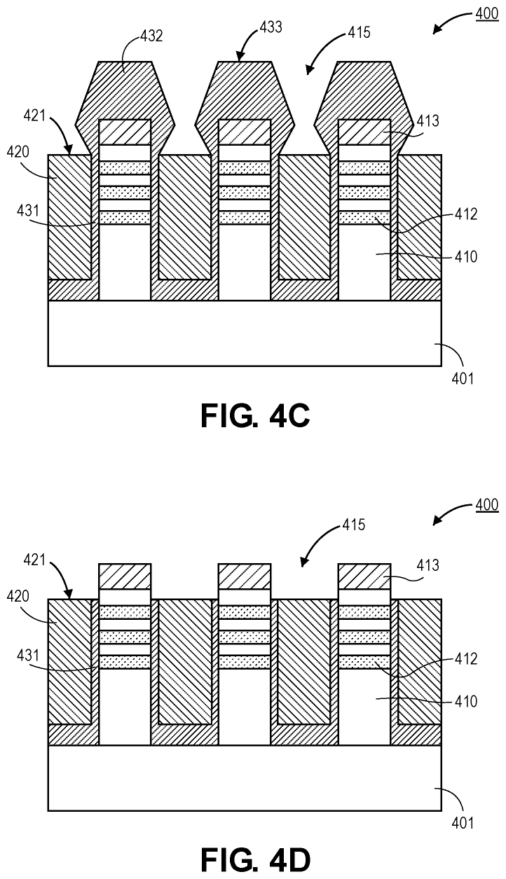

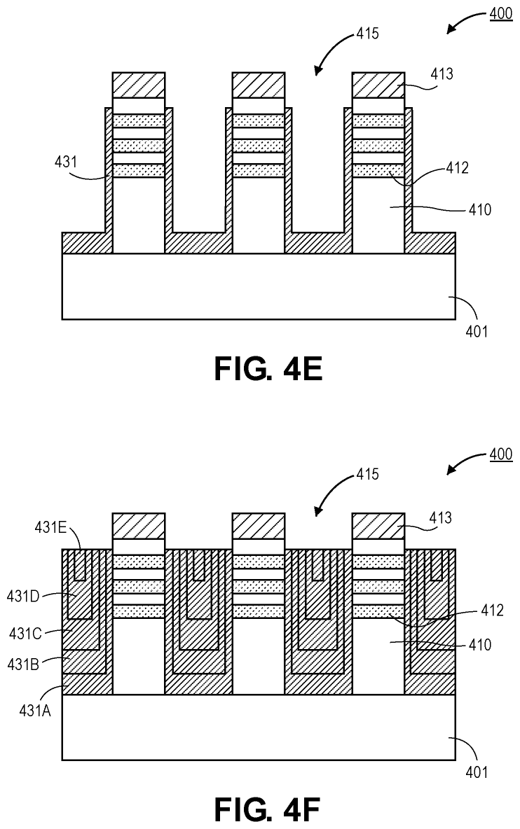

Referring now to FIGS. 4A-4F, a series of cross-sectional illustrations depicting a process for filling trenches 415 in a semiconductor device 400 is shown, in accordance with an embodiment. In an embodiment, the process illustrated includes the use of a sacrificial carbon layer 420 that is deposited with a pulsed plasma FCVD process similar to any of the pulsed plasma FCVD processes disclosed in greater detail herein. The material that is used to fill the trenches 415 may provide shallow trench isolation (STI) between the fins 410.

Referring now to FIG. 4A, a cross-sectional illustration of a semiconductor device 400 is shown, in accordance with an embodiment. In an embodiment, the semiconductor device 400 comprises a substrate 401 with fins 410 that extend up from the substrate 401. In an embodiment, the substrate 401 may be a semiconductor material, such as silicon or the like. The fins 410 may also be a semiconductor material. The fins 410 may be the same material as the substrate 401, or the fins 410 may be a different material than the substrate 401.

In an embodiment, the fins 410 may further comprise a stack of nano-sheets 412 (or nano-wires). The nano-sheets 412 may be a different semiconductor material than the fins 410. In some embodiments, the nano-sheets 412 may comprise a III-V semiconductor material. In one application, the nano-sheets 412 may comprise a SiGe composition. The nano-sheets 412 may have a thickness that is up to approximately 20 nm, up to approximately 10 nm, or up to approximately 5 nm. While three nano-sheets 412 are shown in each fin 410, it is to be appreciated that any number of nano-sheets 412 may be used. The nano-sheets 412 may be used in order to fabricate GAA transistor devices in the semiconductor device 400. For example, the nano-sheets 412 will function as the channel of the GAA transistor. In an embodiment, a hardmask 413 may be provided over a top surface of the fins 410. The hardmask 413 may be any suitable material that can function as an etch mask in order to pattern the fins 410 into the substrate 401.

In an embodiment, the fins 410 are high aspect ratio features similar to the fins 110 described in greater detail above. The fins 410 may be spaced from each other in order to form trenches 415 between fins 410. The trenches 415 may also be high aspect ratio features, similar to trenches 115 described in greater detail above. The aspect ratio of the trenches 415 may result in 3D features that are difficult to fill.

In order to provide STI material between the fins 410, a sacrificial process may be used. In an embodiment, that process may begin with the deposition of a first layer 431 over the fins 410 and the substrate 401. In an embodiment, the first layer 431 comprises the material that is to be used for the STI. For example, the first layer 431 may be a dielectric or insulator, such as a material comprising one or more of silicon and oxygen (e.g., SiO₂), silicon and nitrogen (e.g., SiN), silicon, oxygen, and carbon (e.g., SiOC), silicon, oxygen, carbon, and nitrogen (e.g., SiOCN), silicon, carbon, and nitrogen (e.g., SiCN), or the like. In an embodiment, the first layer 431 may also comprise metallic materials, metallic oxides, or the like. The deposition of the first layer 431 may be a generally conformal process that uses ALD, PE-ALD, CVD, or PE-CVD processes. In some embodiments, the upper end of the fins 410 are covered by an overgrowth region 432 of the first layer 431. If the first layer 431 is allowed to continue growing, the overgrowth regions 432 will pinch together and result in void formation.

Referring now to FIG. 4B, a cross-sectional illustration of the semiconductor device 400 after a second layer 420 is deposited is shown, in accordance with an embodiment. In an embodiment, the second layer 420 may be a sacrificial layer. That is, the second layer 420 may not persist into the final structure of the semiconductor device 400. In an embodiment, the second layer 420 may be a flowable carbon containing material. For example, the second layer 420 may be deposited with a bottom-up filling process. In one embodiment, a pulsed plasma FCVD process similar to process 360 may be used in order to deposit the second layer 420.

In an embodiment, the second layer 420 is deposited to a depth that fills the trenches 415. The second layer 420 may also extend up past a top surface 433 of the first layer 431 (i.e., the top of the overgrowth region 432). That is, the top surface 421 of the second layer 420 may be above the top surface of the first layer 431 after the initial deposition.

Referring now to FIG. 4C, a cross-sectional illustration of the semiconductor device 400 after a recessing operation is shown, in accordance with an embodiment. In an embodiment, the second layer 420 is recessed with an etching process. The etching process may include any etching chemistry that is selective to the second layer 420 over the first layer 431. For example, an oxygen plasma etch or a hydrogen plasma etch may be used to recess a carbon based second layer 420. In an embodiment, the second layer 420 is recessed to a depth that positions the top surface 421 of the second layer 420 below a bottom of the overgrowth region 432 of the first layer 431. In some instances, the top surface 421 of the second layer 420 may be below the top of the fins 410. The top surface 421 of the second layer 420 may also be above a topmost nano-sheet 412.

Referring now to FIG. 4D, a cross-sectional illustration of the semiconductor device 400 after an etching process to remove the overgrowth region 432 of the first layer 431 is shown, in accordance with an embodiment. In an embodiment the etching process may include any etching chemistry that is selective to the first layer 431 over the second layer 420. For example, a fluorine based etching chemistry (with or without carbon) may be used in some embodiments. Other etching chemistries may include one or more of H₂, NF₃, O₃, fluorocarbons (e.g., CH₄), or the like.

Referring now to FIG. 4E, a cross-sectional illustration of the semiconductor device 400 after the second layer 420 is removed is shown, in accordance with an embodiment. In an embodiment, the second layer 420 is removed with an ashing process with O₂ or H₂ plasma, or the like. The removal of the second layer 420 exposes the trenches 415 again. Additionally, the trenches 415 are no longer obstructed by the overgrowth region 432. The first layer 431 remains lining the trench 415. For example, the first layer 431 may have a U-shaped cross-section with a bottom portion on the substrate 401 and vertical portions extending up the sidewalls of the fins 410.

Referring now to FIG. 4F, a cross-sectional illustration of the semiconductor device 400 after a plurality of cycles through the operating processes shown in FIGS. 4A-4E is shown, in accordance with an embodiment. As shown, a plurality of first layers 431A-431E are used to fill the trenches 415. Each of the first layers 431B-431E may be nested into the previously formed first layer 431A-431D. In the illustration of FIG. 4F, the different layers 431A-431E are depicted as separate layers with defined seams between them. However, this is for illustrative purposes in order to depict the processing sequence. In reality, distinct seams or regions between each iteration of the deposition cycle may not be visible and/or otherwise detectible.

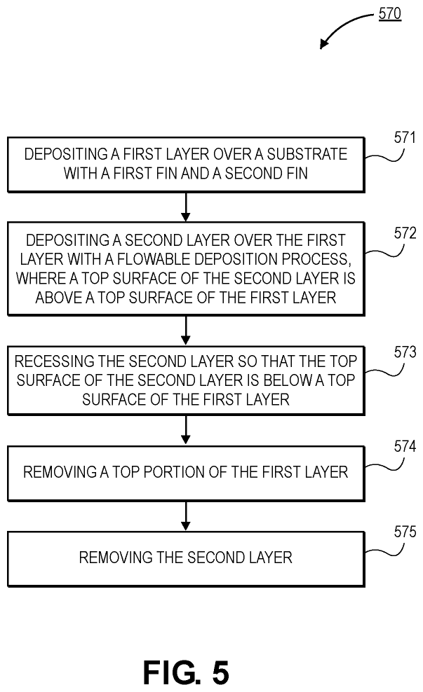

Referring now to FIG. 5, a process flow diagram of a process 570 for filling a trench with a first layer using a sacrificial layer deposited with a pulsed plasma FCVD process is shown, in accordance with an embodiment. In an embodiment, the process 570 may be similar to the process depicted in FIGS. 4A-4F.

In an embodiment, process 570 may begin with operation 571, which comprises depositing a first layer over a substrate with a first fin and a second fin. In an embodiment, the first layer may comprise a dielectric or insulator, such as one or more of SiO₂, SiN, SiOC, SiOCN, SiCN, or the like. In an embodiment, the first layer may also comprise metallic materials, metallic oxides, or the like. The deposition of the first layer may be a generally conformal process that uses ALD, PE-ALD, CVD, or PE-CVD processes.

In an embodiment, the process 570 may continue with operation 572, which comprises depositing a second layer over the first layer with a flowable deposition process. In an embodiment, a top surface of the second layer is above a top surface of the first layer after the deposition process. In an embodiment, the flowable deposition process may be similar to the pulsed plasma FCVD process 360 described in greater detail herein. The second layer may comprise a carbon based material.

In an embodiment, the process 570 may continue with operation 573, which comprises recessing the second layer so that the top surface of the second layer is below a top surface of the first layer. In an embodiment, recessing process may include an ashing process, an oxygen plasma etch, a hydrogen plasma etch, or the like.

In an embodiment, the process 570 may continue with operation 574, which comprises removing a top portion of the first layer. The top portion of the first layer may be the portion of the first layer that is provided above the top surface of the second layer. In an embodiment, any suitable etching process that is selective to the first layer over the second layer may be used.

In an embodiment, the process 570 may continue with operation 575, which comprises removing the second layer. The second layer may be removed with an ashing process, an oxygen plasma etch, a hydrogen plasma etch, or the like. The remaining portion of the first layer may be a U-shaped liner that covers the substrate and sidewalls of the first fin and the second fin. Further, the top of the trench between the first fin and the second fin is open to allow for subsequent deposition.

In an embodiment, the operations 571-575 may be repeated any number of times in order to fill the trench between the first fin and the second fin. In an embodiment, the operations 571-575 may be repeated two or more times, five or more times, or ten or more times.

Embodiments disclosed herein may also include bottom nitride isolation structures between fins. In such embodiments, a nitride film is deposited as a liner along the fins and the surface of the substrate between the fins. A flowable carbon film is then deposited at the bottom of the liner. The top portion of the liner can be etched, and the carbon film is removed. As such, a nitride layer remains at a bottom of the trench.

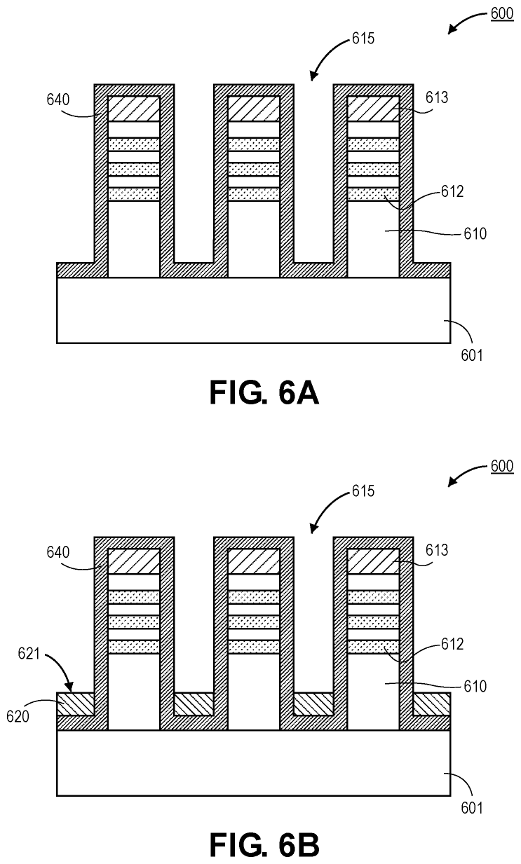

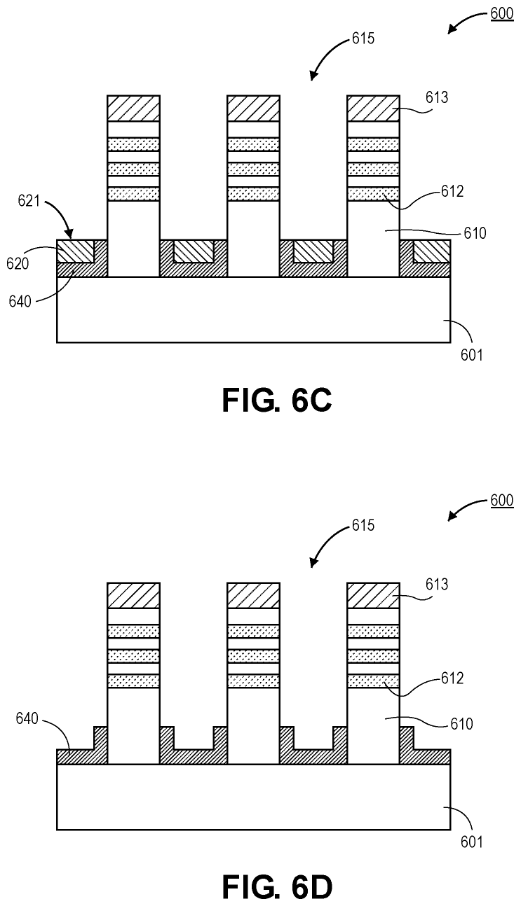

Referring now to FIGS. 6A-6D, a series of cross-sectional illustrations depicting a process for forming a nitride isolation layer 640 between fins 610 is shown, in accordance with an embodiment. In an embodiment, the process illustrated includes the use of a sacrificial carbon layer 620 that is deposited with a pulsed plasma FCVD process similar to any of the pulsed plasma FCVD processes disclosed in greater detail herein.

Referring now to FIG. 6A, a cross-sectional illustration of a semiconductor device 600 is shown, in accordance with an embodiment. In an embodiment, the semiconductor device 600 comprises a substrate 601 with fins 610 that extend up from the substrate 601. In an embodiment, the substrate 601 may be a semiconductor material, such as silicon or the like. The fins 610 may also be a semiconductor material. The fins 610 may be the same material as the substrate 601, or the fins 610 may be a different material than the substrate 601.

In an embodiment, the fins 610 may further comprise a stack of nano-sheets 612 (or nano-wires). The nano-sheets 612 may be a different semiconductor material than the fins 610. In some embodiments, the nano-sheets 612 may comprise a III-V semiconductor material. The nano-sheets 612 may be similar to nano-sheets 412 described in greater detail above. For example, the nano-sheets 612 may be used in order to fabricate GAA transistor devices in the semiconductor device 600. In an embodiment, a hardmask 613 may be provided over a top surface of the fins 610.

In an embodiment, the fins 610 are high aspect ratio features similar to the fins 110 described in greater detail above. The fins 610 may be spaced from each other in order to form trenches 615 between fins 610. The trenches 615 may also be high aspect ratio features, similar to trenches 115 described in greater detail above. The aspect ratio of the trenches 615 may result in 3D features that are difficult to fill.

In order to provide a nitride material between the fins 610, a sacrificial process may be used. In an embodiment, that process may begin with the deposition of a first layer 640 over the fins 610 and the substrate 601. In an embodiment, the first layer 640 comprises the material that is to be used for a nitride insulator. For example, the first layer 640 may comprise silicon and nitrogen (e.g., SiN), silicon, oxygen, carbon, and nitrogen (e.g., SiOCN), silicon, carbon, and nitrogen (e.g., SiCN), or the like. The deposition of the first layer 640 may be a generally conformal process that uses ALD, PE-ALD, CVD, or PE-CVD processes. While shown as being perfectly conformal, the first layer 640 may also form some overgrowth regions similar to those described in greater detail above. However, growth of the first layer 640 is halted before overgrowth regions pinch together to form voided regions.

Referring now to FIG. 6B, a cross-sectional illustration of the semiconductor device 600 after a second layer 620 is deposited is shown, in accordance with an embodiment. In an embodiment, the second layer 620 may be a sacrificial layer. That is, the second layer 620 may not persist into the final structure of the semiconductor device 600. In an embodiment, the second layer 620 may be a flowable carbon containing material. For example, the second layer 620 may be deposited with a bottom-up filling process. In one embodiment, a pulsed plasma FCVD process similar to process 360 may be used in order to deposit the second layer 620. In an embodiment, the second layer 620 is deposited to a thickness that is less than a depth of the trenches 615. That is, the first layer 640 may extend above a top surface 621 of the second layer 620.

Referring now to FIG. 6C, a cross-sectional illustration of the semiconductor device 600 after the first layer 640 is etched back is shown, in accordance with an embodiment. In an embodiment the etching process may include any etching chemistry that is selective to the first layer 640 over the second layer 620. For example, a fluorine based etching chemistry (with or without carbon) may be used in some embodiments. Other etching chemistries may include one or more of H₂, NF₃, O₃, fluorocarbons (e.g., CH₄), or the like. In an embodiment, the second layer 620 protects the portion of the first layer 640 that is over the surface of the substrate 601 at the bottom of the trench 615.

Referring now to FIG. 6D, a cross-sectional illustration of the semiconductor device 600 after the second layer 620 is removed is shown, in accordance with an embodiment. In an embodiment, the second layer 620 is removed with an ashing process or the like. The removal of the second layer 620 exposes the entirety of the remaining portions of first layer 640 at the bottom of the trench 615. In an embodiment, the first layer 640 lining the trench 615 may have a U-shaped cross-section with a bottom portion on the substrate 601 and vertical portions extending up the sidewalls of the fins 610.

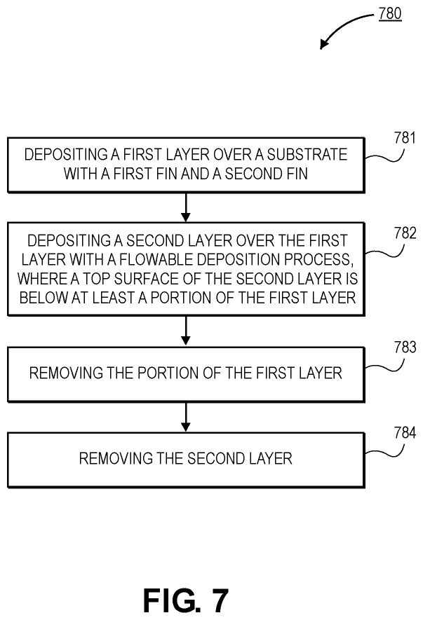

Referring now to FIG. 7, a process flow diagram of a process 780 for forming a nitride isolation in a trench between fins using a sacrificial layer deposited with a pulsed plasma FCVD process is shown, in accordance with an embodiment. In an embodiment, the process 780 may be similar to the process depicted in FIGS. 6A-6D.

In an embodiment, the process 780 may begin with operation 781, which comprises depositing a first layer over a substrate with a first fin and a second fin. In an embodiment, the first layer may be a material comprising nitride, such as SiN, SiOCN, SiCN, or the like. The first layer may be deposited with a conformal deposition process, such as an ALD process, a PE-ALD process, a CVD process, a PE-CVD process, or the like.

In an embodiment, the process 780 may continue with operation 782, which comprises depositing a second layer over the first layer with a flowable deposition process. In an embodiment, a top surface of the second layer is below at least a portion of the first layer. That is, while the first layer may extend up the entire height of the fins, the second layer may fill a bottom portion of the trench between the fins. The second layer may be a carbon containing material that is deposited with a pulsed plasma FCVD process, such as process 360 described in greater detail herein.

In an embodiment, the process 780 may continue with operation 783, which comprises removing the portion of the first layer. The portion of the first layer may be removed with any etching process that is selective to the first layer over the second layer. For example, a fluorine based etching chemistry (with or without carbon) may be used in some embodiments. Other etching chemistries may include one or more of H₂, NF₃, O₃, fluorocarbons (e.g., CH₄), or the like. In an embodiment, the second layer protects a lower portion of the first layer that is over the surface of the substrate at the bottom of the trench between the fins.

In an embodiment, the process 780 continues with operation 784, which comprises removing the second layer. The second layer may be removed with an ashing process, an oxygen plasma etch, a hydrogen plasma etch, or the like. The remaining portion of the first layer may have a U-shaped cross-section at the bottom of the trench between the fins.

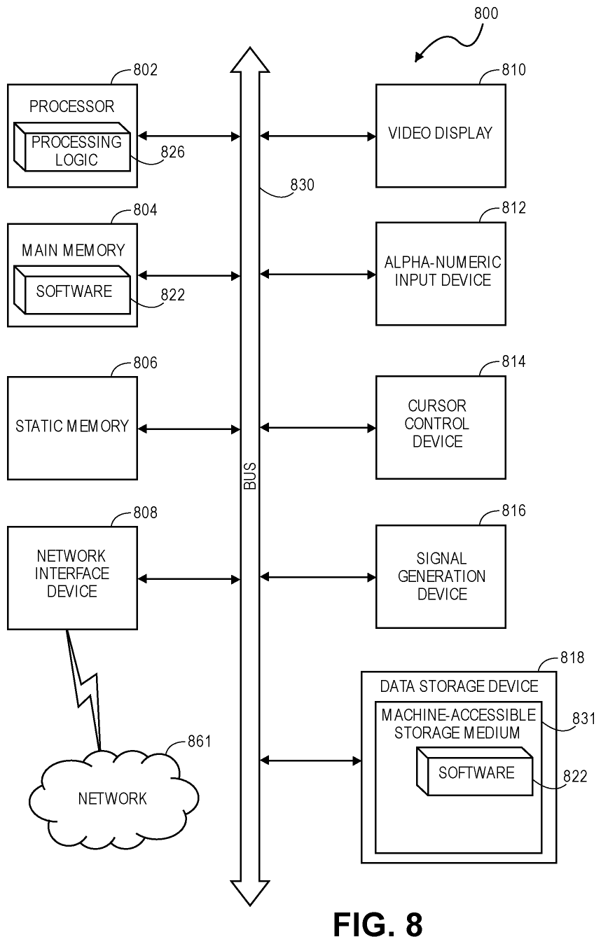

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 831 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 861 via the system network interface device 808. In an embodiment, the network interface device 808 may operate using RF coupling, optical coupling, acoustic coupling, or inductive coupling.

While the machine-accessible storage medium 831 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of depositing a carbon layer on a substrate, comprising:
flowing a first precursor comprising carbon into a chamber;
flowing a second precursor comprising nitrogen into the chamber; and
applying a pulsed RF plasma source to the first precursor and the second precursor, wherein the first precursor and the second precursor react in response to the pulsed RF plasma source to form a flowable polymerized layer that is deposited on the substrate.

2. The method of claim 1, wherein the first precursor comprises an organic molecule that comprises vinyl species or acetylene.

3. The method of claim 2, wherein the first precursor comprises 5-vinyl-2-norbornene or hexadiene.

4. The method of claim 1, wherein the second precursor comprises ammonia.

5. The method of claim 1, further comprising:
flowing one or more of argon, helium, nitrogen, or hydrogen into the chamber with the first precursor and/or the second precursor.

6. The method of claim 1, wherein the substrate comprises a trench, and wherein the carbon layer fills the trench with a bottom-up fill process that is void-free.

7. A method for filling a trench on a substrate, comprising:
depositing a first layer over the substrate that comprises a first fin and a second fin, wherein the trench is between the first fin and the second fin;
depositing a second layer over the first layer with a flowable deposition process, wherein a top surface of the second layer is above a top surface of the first layer;
recessing the second layer so that the top surface of the second layer is below a top surface of the first layer;
removing a top portion of the first layer; and
removing the second layer.

8. The method of claim 7, wherein the first layer comprises one or more of silicon, oxygen, nitrogen, or carbon, and wherein the second layer comprises carbon.

9. The method of claim 7, wherein the first layer is deposited with an atomic layer deposition (ALD) process, a plasma enhanced ALD (PE-ALD) process, a chemical vapor deposition (CVD) process, or a plasma enhanced CVD (PE-CVD) process.

10. The method of claim 7, wherein the second layer is deposited with a flowable chemical vapor deposition (FCVD) process.

11. The method of claim 10, wherein the FCVD process comprises a first precursor comprising carbon, a second precursor comprising nitrogen, and a pulsed RF plasma source.

12. The method of claim 7, wherein the method is repeated a plurality of times to fully fill the trench.

13. A method for forming an isolation layer at a bottom of a trench on a substrate, comprising:
depositing a first layer over the substrate with a first fin and a second fin, wherein the trench is between the first fin and the second fin;
depositing a second layer over the first layer with a flowable deposition process, where a top surface of the second layer is below at least a portion of the first layer;
removing the portion of the first layer; and
removing the second layer.

14. The method of claim 13, wherein the first layer comprises nitrogen.

15. The method of claim 13, wherein the second layer comprises carbon.

16. The method of claim 13, wherein the second layer is deposited with a flowable chemical vapor deposition (FCVD) process.

17. The method of claim 16, wherein the FCVD process comprises a first precursor comprising carbon, a second precursor comprising nitrogen, and a pulsed RF plasma source.

18. The method of claim 16, wherein the first layer has a U-shaped cross-section.

19. The method of claim 13, wherein nano-wire structures are embedded in the first fin and the second fin.

20. The method of claim 13, wherein the second layer is removed with an ashing process.
